(19) United States
(12) Patent Application Publication
(10) Pub. No.: US 2025/0185180 A1
(43) Pub. Date: Jun. 5, 2025

(54) PRINTED CIRCUIT BOARD AND MANUFACTURING METHOD THEREOF

(71) Applicant: SAMSUNG ELECTRO-MECHANICS CO., LTD., Suwon-si (KR)

(72) Inventor: Chanhoon Ko, Suwon-si (KR)

(73) Assignee: SAMSUNG ELECTRO-MECHANICS CO., LTD., Suwon-si (KR)

(21) Appl. No.: 18/795,758

(22) Filed: Aug. 6, 2024

(30) Foreign Application Priority Data
Dec. 1, 2023 (KR) 10-2023-0172624

(51) Int. Cl. H05K 3/40; H05K 1/11

(52) U.S. Cl. CPC H05K 3/4007; H05K 1/111; H05K 2201/0338; H05K 2201/0367; H05K 2201/09845; H05K 2203/1377

(57) ABSTRACT

A printed circuit board may include an insulation layer, a wire layer located within the insulation layer, a protective layer located on the insulation layer, a contact portion including a first connecting portion located within the insulation layer and the protective layer and a second connecting portion protruding above the protective layer, and a protective pattern located between the protective layer and the first connecting portion of the contact portion.

### CROSS-REFERENCE TO RELATED APPLICATION

This application claims priority to and the benefit of Korean Patent Application No. 10-2023-0172624 filed in the Korean Intellectual Property Office on Dec. 1, 2023, the entire contents of which is incorporated herein by reference.

### BACKGROUND

### 1. Technical Field

The present disclosure relates to a printed circuit board and a manufacturing method thereof.

### 2. Description of the Related Art

As electronic devices in the IT field, including mobile phones, become smaller, the size of the metal posts formed on printed circuit boards on which electronic components are mounted is also becoming smaller.

After forming all of the plurality of wiring layers in the printed circuit board, when forming a metal post to overlap the pad portion of the printed circuit board, the position and thickness of the pad portion of the printed circuit board may change due to the heat generated when forming the plurality of wiring layers, thereby possibly causing an alignment error between the pad portion and metal post.

Meanwhile, if a recess or the like occurs on the surface of the metal post, the coupling force between the printed circuit board and the electronic component may decrease.

### SUMMARY

The present disclosure attempts to provide a printed circuit board and a manufacturing method thereof capable of preventing a recess from being generated on the surface of metal post and preventing an alignment error between a pad portion and a metal post.

However, the problem to be solved by the embodiments is not limited to the above-described problem, and can be variously extended within the scope of the technical spirit included in the embodiments.

A printed circuit board may include an insulation layer, a wire layer located within the insulation layer, a protective layer located on the insulation layer, a contact portion including: a first connecting portion located within the insulation layer and the protective layer, and a second connecting portion protruding above the protective layer, and a protective pattern located between the protective layer and the first connecting portion of the contact portion.

The first connecting portion of the contact portion may include a pad portion located within the insulation layer, and a first connecting portion located within the protective layer.

The pad portion and the first connecting portion may be directly connected.

The first connecting portion and the second connecting portion may be integrally formed.

The contact portion and the protective pattern may include different metals.

A thickness of the protective pattern may be thinner than a thickness of the pad portion of the contact portion and a thickness of the first connecting portion of the contact portion.

The wire layer may include a first wire layer, and a second wire layer located on the wire layer.

The first wire layer may include the same metal as the contact portion.

The second wire layer may include the same metal as the protective pattern.

A thickness of the second wire layer may be thinner than a thickness of the first wire layer.

Along a height direction, a first width of the second connecting portion may be substantially constant.

Along a planar direction that is substantially parallel to a surface of the insulation layer, a first width of the second connecting portion and a second width of the first connecting portion may be different from each other.

Along a height direction that is substantially perpendicular to the planar direction, the second width of the first connecting portion may be substantially constant.

Along a planar direction that is substantially parallel to a surface of the insulation layer, a first width of the second connecting portion and a second width of the first connecting portion may be substantially the same.

A manufacturing method of a printed circuit board may include forming a dummy insulation layer having a first hole, stacking a protective layer on the dummy insulation layer, and forming a second hole overlapping the first hole in the protective layer, stacking a protective metal layer on the protective layer and within the first hole and the second hole, integrally forming a first connecting portion and a second connecting portion within the first hole and the second hole covered with the protective metal layer, forming a pad portion and a wire layer on the protective metal layer, stacking the insulation layer on the pad portion and the wire layer, exposing the protective metal layer located on the second connecting portion by removing the dummy insulation layer, and forming a protective pattern located between the protective layer and the first connecting portion and the protective layer by removing the protective metal layer on the second connecting portion.

According to an embodiment, a printed circuit board and a manufacturing method thereof capable of preventing a recess from being generated on the surface of metal post and preventing an alignment error between a pad portion and a metal post may be provided.

However, it is obvious that the effect of the embodiments is not limited to the above-described effect, and may be variously extended without departing from the spirit and scope of the embodiments.

### BRIEF DESCRIPTION OF THE DRAWINGS

FIG. 1 is a cross-sectional view of a printed circuit board according to an embodiment.

FIG. 2 to FIG. 15 are cross-sectional views showing a manufacturing method of a printed circuit board according to an embodiment.

FIG. 16 is a cross-sectional view of a printed circuit board according to another embodiment.

FIG. 17 is a cross-sectional view of a printed circuit board according to another embodiment.

FIG. 18 is a cross-sectional view of a printed circuit board according to another embodiment.

FIG. 19 is a cross-sectional view of a printed circuit board according to another embodiment.

FIG. 20 is a cross-sectional view of a printed circuit board according to another embodiment.

### DETAILED DESCRIPTION

The embodiments will be described more fully hereinafter with reference to the accompanying drawings, in which embodiments of this disclosure are shown. As those skilled in the art would realize, the described embodiments may be modified in various different ways, all without departing from the spirit or scope of this disclosure.

To clearly describe the embodiments, parts that are irrelevant to the description are omitted, and like numerals refer to like or similar constituent elements throughout the specification.

The accompanying drawings are provided only in order to allow embodiments disclosed in the present specification to be easily understood and are not to be interpreted as limiting the spirit disclosed in the present specification, and it is to be understood that this disclosure includes all modifications, equivalents, and substitutions without departing from the scope and spirit of this disclosure.

Further, since sizes and thicknesses of constituent members shown in the accompanying drawings are arbitrarily given for better understanding and ease of description, the embodiments are not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

In addition, throughout the specification, “connected” means that two or more components are not only directly connected, but two or more components may be connected indirectly through other components, physically connected as well as being electrically connected, or it may be referred to by different names depending on the location or function, but may mean integral.

The thickness and width of each layer, pattern, and portion disclosed herein may be determined by microscopy such as scanning electron microscopy. Other methods and/or tools appreciated by one of ordinary skill in the art, even if not described in the present disclosure, may also be used.

Hereinafter, various embodiments and variations will be described in detail with reference to drawings.

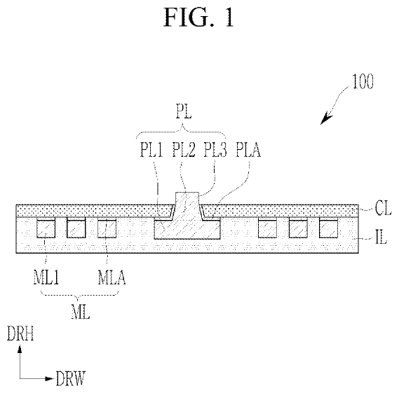

Referring to FIG. 1, a printed circuit board 100 according to an embodiment will be described. FIG. 1 is a cross-sectional view of a printed circuit board according to an embodiment.

Referring to FIG. 1, the printed circuit board 100 according to the present embodiment may include an insulation layer IL, a protective layer CL located on the insulation layer IL, a plurality of wire layers ML located within the insulation layer IL, and a contact portion PL partially located within the insulation layer IL and the protective layer CL and including a portion protruding from the protective layer CL.

The insulation layer IL and the protective layer CL may include different insulating materials. For example, the protective layer CL may include a multi-layer including a PET film, a resin composition, and an OPP film, and the protective layer CL may be an Ajinomoto Build-up Film (ABF), but the embodiment is not limited thereto.

The plurality of wire layers ML may include a first wire layer ML1 located within the insulation layer IL and a second wire layer MLA located on the first wire layer ML1. The second wire layer MLA may contact the protective layer CL. Along a height direction DRH perpendicular to a planar direction DRW parallel to a surface of the protective layer CL, a thickness of the second wire layer MLA may be thinner than a thickness of the first wire layer ML1. In some embodiments of the application, the height direction DRH may be substantially perpendicular to the planar direction DRW, which in turn may be substantially parallel to a surface of the protective layer CL. The term “substantially perpendicular” may mean that the planar direction deviates from the height direction DRH by less than 1°. The term “substantially parallel” may mean that the planar direction deviates from the surface of the protective layer CL by less than 1°.

The first wire layer ML1 and the second wire layer MLA may include different metal layers. For example, the first wire layer ML1 may include copper, and the second wire layer MLA may include nickel. However, the embodiment is not limited thereto.

The contact portion PL may include a pad portion PL1 located within the insulation layer IL, a first connecting portion PL2 located on the pad portion PL1 and located within the protective layer CL, and a second connecting portion PL3 located on the first connecting portion PL2 and protruding above the protective layer CL.

A protective pattern PLA may be located between the contact portion PL and the protective layer CL. In more detail, the protective pattern PLA may include the protective pattern PLA located between the pad portion PL1 and the protective layer CL and between the first connecting portion PL2 and the protective layer CL.

Along the height direction DRH, a thickness of the protective pattern PLA may be thinner than a thickness of the pad portion PL1, a thickness of the first connecting portion PL2, and a thickness of the second connecting portion PL3.

The pad portion PL1 of the contact portion PL may include the same metal as the first wire layer ML1, and the protective pattern PLA may include the same metal as the second wire layer MLA.

The first connecting portion PL2 and the second connecting portion PL3 of the contact portion PL may include the same metal as the pad portion PL1 of the contact portion PL.

The pad portion PL1 of the contact portion PL may be directly connected to the first connecting portion PL2 of the contact portion PL, and the second connecting portion PL3 of the contact portion PL may be directly connected to the first connecting portion PL2 of the contact portion PL.

Along the height direction DRH, a width of the first connecting portion PL2 of the contact portion PL may be wide at the bottom and may narrow toward the top. Therefore, the pad portion PL1 of the contact portion PL and the first connecting portion PL2 of the contact portion PL may be stably connected to each other.

Along the height direction DRH, a width of the second connecting portion PL3 of the contact portion PL may be substantially constant. The term “substantially constant” may mean that the widths of the second connecting portion PL3 at different heights differ by less than 1%.

As the pad portion PL1 of the contact portion PL and the first connecting portion PL2 of the contact portion PL are directly connected to each other without an intermediate layer such as a seed layer, connection properties between the pad portion PL1 of the contact portion PL and the first connecting portion PL2 and the second connecting portion PL3 of the contact portion PL may be enhanced, and the occurrence of alignment errors may be reduced.

Since the protective pattern PLA is located between the pad portion PL1 and the protective layer CL and between the first connecting portion PL2 and the protective layer CL such that the second connecting portion PL3 of the contact portion PL is protected during the manufacturing process, recesses or the like may not occur on a surface of the second connecting portion PL3 of the contact portion PL protruded on the protective layer CL, such that deterioration of contact properties with respect to the contact portion PL and external electronic devices may be prevented.

In the illustrated embodiment, the first connecting portion PL2 and the second connecting portion PL3 of the contact portion PL is illustrated to be located on a central portion of the pad portion PL1 of the contact portion PL, but embodiment is not limited thereto, and the embodiment may include all cases in which the first connecting portion PL2 and the second connecting portion PL3 of the contact portion PL are located on the pad portion PL1 of the contact portion PL.

Although not shown in the drawings, according to another embodiment, via connected to at least one of the plurality of wire layers ML within the insulation layer IL may be further included, an additional insulation layer located on the insulation layer IL may be further included, an additional via located within the additional insulation layer may be further included, and an additional wire layer buried within the additional insulation layer may be further included.

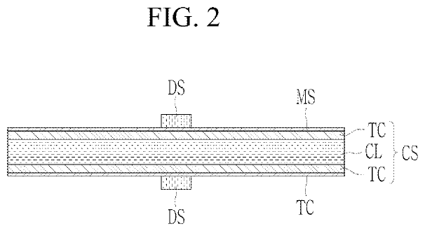

Then, referring to FIG. 2 to FIG. 16, together with FIG. 1, a manufacturing method of a printed circuit board according to an embodiment will be described. FIG. 2 to FIG. 16 are cross-sectional views showing a manufacturing method of a printed circuit board according to an embodiment.

Referring to FIG. 2, a copper foil layer MS and a dummy pattern DS may be formed on a carrier substrate CS that includes a core portion CP and a thin film metal layer TC stacked on both sides of the core portion CP.

The dummy pattern DS may be formed at a location where the second connecting portion PL3 of the contact portion PL is formed.

The dummy pattern DS may include a photosensitive material, and the dummy pattern DS may be a dry film, but the embodiment is not limited thereto.

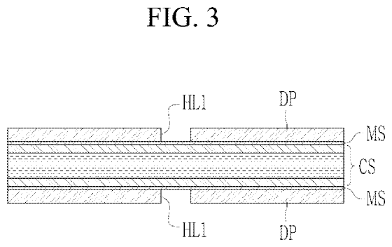

Referring to FIG. 3, a first hole HL1 may be formed on the dummy layer DP by stacking a dummy layer DP on the dummy pattern DS and removing the dummy pattern DS. The first hole HL1 of the dummy layer DP may be formed at a portion where the dummy pattern DS is removed.

The dummy layer DP may include the same metal as the copper foil layer MS, and for example, the copper foil layer MS and the dummy layer DP may include copper, but the embodiment is not limited thereto. The dummy layer DP may be formed from the copper foil layer MS by plating, but the embodiment is not limited thereto.

According to another embodiment, the dummy layer DP may include an insulating material. When the dummy layer DP includes an insulating material, an insulating material having a different etching condition from a protective insulation layer CLA to be described later may be included.

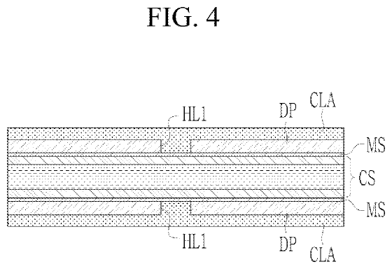

Referring to FIG. 4, the protective insulation layer CLA on the dummy layer DP including the first hole HL1 may be stacked. The protective insulation layer CLA may be formed inside the first hole HL1 and on the dummy layer DP.

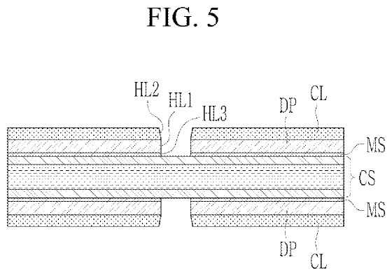

Referring to FIG. 5, a second hole HL2 overlapping the first hole HL1 in the protective insulation layer CLA may be formed, and the copper foil layer MS overlapping the first hole HL1 and the second hole HL2 may be removed, such that a third hole HL3 may be formed in the copper foil layer MS. The protective insulation layer CLA having the second hole HL2 may be the protective layer CL.

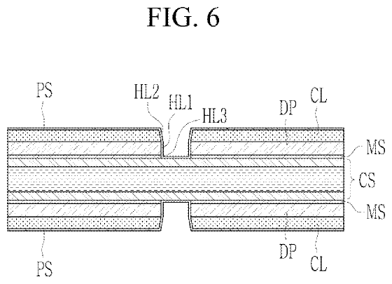

Referring to FIG. 6, a first metal layer PS on the protective layer CL and on the first hole HL1, the second hole HL2, and the third hole HL3 may be stacked. A thickness of the first metal layer PS may be thinner than a thickness of the dummy layer DP and the protective layer CL.

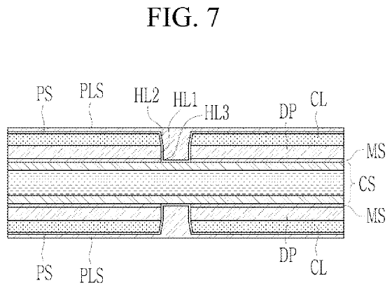

Referring to FIG. 7, a second metal layer PLS may be stacked on the first metal layer PS. The second metal layer PLS may be formed on the first metal layer PS located on the protective layer CL and within the first hole HL1, the second hole HL2, and the third hole HL3 covered with the first metal layer PS.

The second metal layer PLS may include a different metal from the first metal layer PS. The second metal layer PLS may include copper, and the first metal layer PS may include nickel. However, the embodiment is not limited thereto.

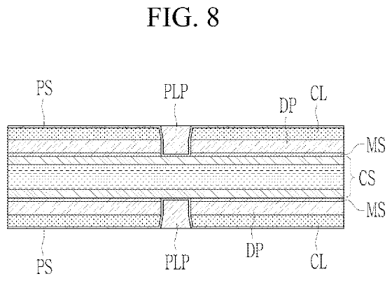

Referring to FIG. 8, a portion of the second metal layer PLS located on the first metal layer PS located on the protective layer CL may be removed and a portion of the second metal layer PLS located within the first hole HL1, the second hole HL2, and the third hole HL3 covered with the first metal layer PS may be maintained, such that a connection pattern PLP located within the first hole HL1, the second hole HL2, and the third hole HL3 may be formed.

The connection pattern PLP may correspond to the first connecting portion PL2 and the second connecting portion PL3.

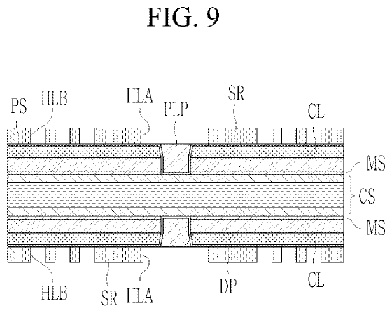

Referring to FIG. 9, a photosensitive layer SR having a first opening HLA and a second opening HLB may be formed on the first metal layer PS located on the protective layer C. The photosensitive layer SR may include a photosensitive material, and for example, the photosensitive layer SR may be a dry film, but the embodiment is not limited thereto.

The first opening HLA of the photosensitive layer SR may overlap the connection pattern PLP, and may be formed at a location where the pad portion PL1 is to be formed.

The second opening HLB of the photosensitive layer SR may be formed at a location corresponding to the first wire layer ML1 of the plurality of wire layers ML.

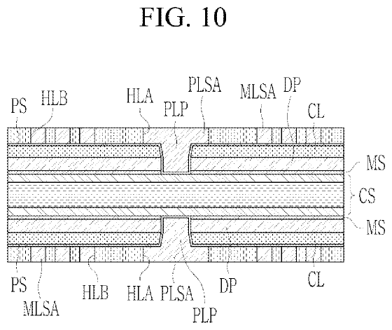

Referring to FIG. 10, by stacking a third metal layer within the first opening HLA and the second opening HLB the photosensitive layer SR, a pad pattern PLSA within the first opening HLA of the photosensitive layer SR may be formed, and a wire pattern MLSA within the second opening HLB of the photosensitive layer SR may be formed.

The pad pattern PLSA may correspond to the pad portion PL1, and the wire pattern MLSA may correspond to the first wire layer ML1.

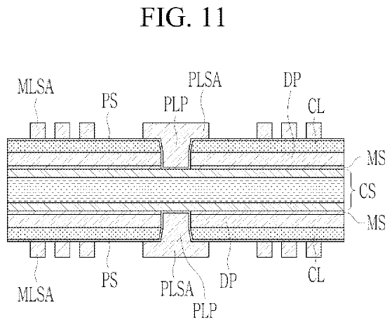

Referring to FIG. 11, the photosensitive layer SR may be removed.

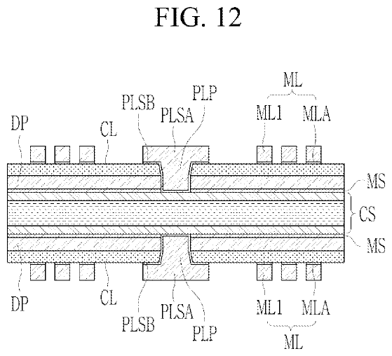

Referring to FIG. 12, by removing the first metal layer PS by using the pad pattern PLSA and the wire pattern MLSA as an etching mask, the plurality of wire layers ML including the first wire layer ML1 and the second wire layer MLA may be formed, and a dummy pattern PLSB contacting the pad pattern PLSA and the connection pattern PLP may be formed.

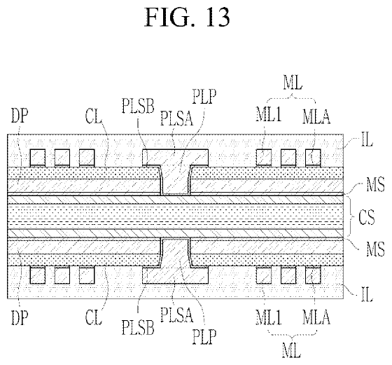

Referring to FIG. 13, the insulation layer IL may be stacked on the plurality of wire layers ML and the pad pattern PLSA.

Although not shown in the drawings, according to another embodiment, a via hole and a via connected to at least one of the plurality of wire layers ML within the insulation layer IL may be formed, the additional insulation layer on the insulation layer IL may be formed, an additional via hole and via may be formed within the additional insulation layer, and an additional wire layer buried within the additional insulation layer may be further formed.

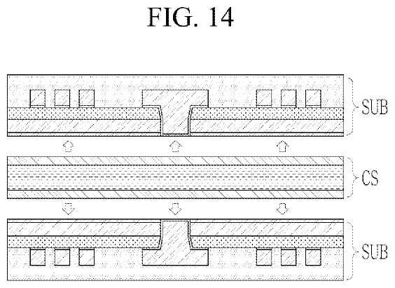

Subsequently, as shown in FIG. 14, a substrate portion SUB is peeled from both sides of the carrier substrate CS.

Hereinafter, one substrate portion SUB peeled from the carrier substrate CS will be described.

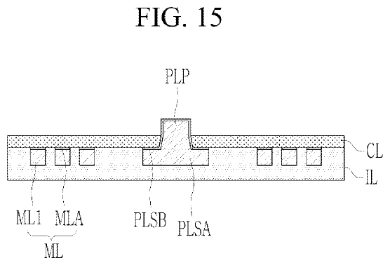

Referring to FIG. 15, the copper foil layer MS and the dummy layer DP may be removed. By removing the copper foil layer MS and the dummy layer DP, the dummy pattern PLSB located on the connection pattern PLP protruding above the protective layer CL may be exposed.

In the illustrated embodiment, the copper foil layer MS and the dummy layer DP are removed together, but according to another embodiment, the copper foil layer MS and the dummy layer DP may be removed separately.

According to another embodiment, the dummy layer DP may be an insulation layer that is not a metal layer, and when the dummy layer DP is an insulation layer, the protective layer CL and etching condition may be different from each other, and the dummy layer DP may be removed without removing the protective layer CL.

Subsequently, the dummy pattern PLSB located on the connection pattern PLP protruding more than the protective layer CL may be removed, and thereby the printed circuit board 100 shown in FIG. 1 may be formed.

According to a manufacturing method of a printed circuit board according to an embodiment, the pad pattern PLSA corresponding to the pad portion PL1 may be formed directly on the connection pattern PLP corresponding to the first connecting portion PL2 and the second connecting portion PL3, such that contact properties between the pad portion PL1 and the first connecting portion PL2 and the second connecting portion PL3 may be enhanced.

According to a manufacturing method of a printed circuit board according to an embodiment, by protecting and covering with the dummy pattern PLSB while forming the pad portion PL1 and the first connecting portion PL2 and the second connecting portion PL3, recesses or the like may be prevented from occurring in the second connecting portion PL3 of the contact portion PL protruding more than the protective layer CL during the manufacturing process, and a decrease of the coupling force between the contact portion PL of the printed circuit board and an electronic device connected to the printed circuit board may be prevented.

According to a manufacturing method of a printed circuit board according to an embodiment, by forming the contact portion PL together while forming the plurality of wire layers ML located within the insulation layer IL, occurrence of alignment errors between a pad portion of a printed circuit board and a connecting portion PL may be reduced.

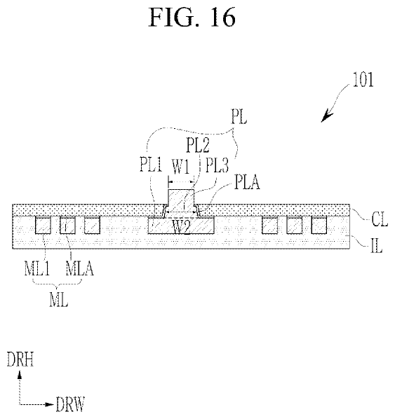

Referring to FIG. 16, a printed circuit board 101 according to another embodiment will be described. FIG. 16 is a cross-sectional view of a printed circuit board according to another embodiment.

Referring to FIG. 16, the printed circuit board 101 according to the present embodiment is similar to the printed circuit board 100 according to an embodiment described above with reference to FIG. 1. The detailed description of the same components is omitted.

Referring to FIG. 16, the printed circuit board 101 according to the present embodiment may include the insulation layer IL, the protective layer CL located on the insulation layer IL, the plurality of wire layers ML located within the insulation layer IL, and the contact portion PL partially located within the insulation layer IL and the protective layer CL and including the portion protruding from the protective layer CL.

The plurality of wire layers ML may include the first wire layer ML1 located within insulation and the second wire layer MLA located on the first wire layer ML1.

The contact portion PL may include the pad portion PL1 located within the insulation layer IL, the first connecting portion PL2 located on the pad portion PL1 and located within the protective layer CL, the second connecting portion PL3 located on the first connecting portion PL2 and protruding above the protective layer CL.

The protective pattern PLA may be located between the contact portion PL and the protective layer CL. In more detail, the protective pattern PLA may include the protective pattern PLA located between the pad portion PL1 and the protective layer CL and between the first connecting portion PL2 and the protective layer CL.

The first wire layer ML1 and the second wire layer MLA may include different metal layers. The pad portion PL1 of the contact portion PL may include the same metal as the first wire layer ML1, and the protective pattern PLA may include the same metal as the second wire layer MLA. For example, the first wire layer ML1 may include copper, and the second wire layer MLA may include nickel. However, the embodiment is not limited thereto.

The pad portion PL1 of the contact portion PL may be directly connected to the first connecting portion PL2 of the contact portion PL, and the second connecting portion PL3 of the contact portion PL may be directly connected to the first connecting portion PL2 of the contact portion PL.

Unlike the printed circuit board 100 according to an embodiment described above, in the printed circuit board 101 according to the present embodiment, along the planar direction DRW, a first width W1 of the second connecting portion PL3 of the contact portion PL may be narrower than a narrowest width among second widths W2 of the first connecting portion PL2 of the contact portion PL. Since the width of the first connecting portion PL2 of the contact portion PL located within the protective layer CL is wider than the second connecting portion PL3 of the contact portion PL protruding above the protective layer CL, even if an external force is applied to the second connecting portion PL3 of the contact portion PL, the influence of the external force is diffused to the first connecting portion PL2 of the contact portion PL, which has a relatively wider width, and thereby concentration of stress due to external force to the second connecting portion PL3 of the contact portion PL may be prevented, such that damage of the contact portion PL due to external stress may be prevented.

According to the present embodiment, similar to the embodiment described above, as the pad portion PL1 of the contact portion PL and the first connecting portion PL2 of the contact portion PL are directly connected to each other without an intermediate layer such as a seed layer, connection properties between the pad portion PL1 of the contact portion PL and the first connecting portion PL2 and the second connecting portion PL3 of the contact portion PL may be enhanced, and the occurrence of alignment errors may be reduced.

In addition, since the protective pattern PLA is located between the pad portion PL1 and the protective layer CL and between the first connecting portion PL2 and the protective layer CL such that the second connecting portion PL3 of the contact portion PL is protected during the manufacturing process, recesses or the like may not occur on the surface of the second connecting portion PL3 of the contact portion PL protruded on the protective layer CL, such that deterioration of contact properties with respect to the contact portion PL and external electronic devices may be prevented.

Various features of a printed circuit board according to an embodiment described above may be all applicable to a printed circuit board according to the present embodiment.

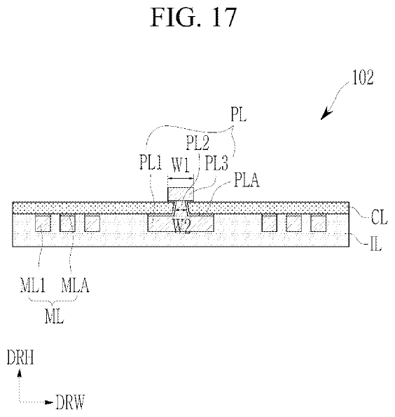

Referring to FIG. 17, a printed circuit board 102 according to another embodiment will be described. FIG. 17 is a cross-sectional view of a printed circuit board according to another embodiment.

Referring to FIG. 17, the printed circuit board 102 according to the present embodiment is similar to printed circuit boards according to the embodiments 100 and 101 described above. The detailed description of the same components is omitted.

Referring to FIG. 17, the printed circuit board 102 according to the present embodiment may include the insulation layer IL, the protective layer CL located on the insulation layer IL, the plurality of wire layers ML located within the insulation layer IL, and the contact portion PL partially located within the insulation layer IL and the protective layer CL and including the portion protruding from the protective layer CL.

The plurality of wire layers ML may include the first wire layer ML1 located within insulation and the second wire layer MLA located on the first wire layer ML1.

The contact portion PL may include the pad portion PL1 located within the insulation layer IL, the first connecting portion PL2 located on the pad portion PL1 and located within the protective layer CL, the second connecting portion PL3 located on the first connecting portion PL2 and protruding above the protective layer CL.

The protective pattern PLA may be located between the contact portion PL and the protective layer CL. In more detail, the protective pattern PLA may include the protective pattern PLA located between the pad portion PL1 and the protective layer CL and between the first connecting portion PL2 and the protective layer CL.

The first wire layer ML1 and the second wire layer MLA may include different metal layers. The pad portion PL1 of the contact portion PL may include the same metal as the first wire layer ML1, and the protective pattern PLA may include the same metal as the second wire layer MLA. For example, the first wire layer ML1 may include copper, and the second wire layer MLA may include nickel. However, the embodiment is not limited thereto.

The pad portion PL1 of the contact portion PL may be directly connected to the first connecting portion PL2 of the contact portion PL, and the second connecting portion PL3 of the contact portion PL may be directly connected to the first connecting portion PL2 of the contact portion PL.

Unlike the printed circuit boards 100 and 101 according to the embodiments described above, in the printed circuit board 102 according to the present embodiment, along the planar direction DRW, the first width W1 of the second connecting portion PL3 of the contact portion PL may be wider than the second width W2 of the first connecting portion PL2 of the contact portion PL. Even if the width of the first connecting portion PL2 of the contact portion PL located within the protective layer CL is narrow, the second connecting portion PL3 of the contact portion PL may be formed wide, and accordingly, deterioration of contact properties with respect to external electronic devices may be prevented.

According to the present embodiment, similar to the embodiments described above, as the pad portion PL1 of the contact portion PL and the first connecting portion PL2 of the contact portion PL are directly connected to each other without an intermediate layer such as a seed layer, connection properties between the pad portion PL1 of the contact portion PL and the first connecting portion PL2 and the second connecting portion PL3 of the contact portion PL may be enhanced, and the occurrence of alignment errors may be reduced.

In addition, since the protective pattern PLA is located between the pad portion PL1 and the protective layer CL and between the first connecting portion PL2 and the protective layer CL such that the second connecting portion PL3 of the contact portion PL is protected during the manufacturing process, recesses or the like may not occur on the surface of the second connecting portion PL3 of the contact portion PL protruded on the protective layer CL, such that deterioration of contact properties with respect to the contact portion PL and external electronic devices may be prevented.

Various features of printed circuit boards according to the embodiments described above may be all applicable to a printed circuit board according to the present embodiment.

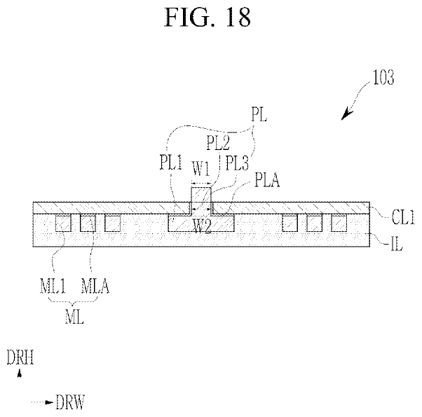

Referring to FIG. 18, a printed circuit board 103 according to another embodiment will be described. FIG. 18 is a cross-sectional view of a printed circuit board according to another embodiment.

Referring to FIG. 18, the printed circuit board 103 according to the present embodiment is similar to printed circuit boards according to the embodiments 100, 101, and 102 described above. The detailed description of the same components is omitted.

Referring to FIG. 18, the printed circuit board 103 according to the present embodiment may include the insulation layer IL, a protective layer CL1 located on the insulation layer IL, the plurality of wire layers ML located within the insulation layer IL, and the contact portion PL partially located within the insulation layer IL and the protective layer CL1 and including the portion protruding from the protective layer CL1.

The plurality of wire layers ML may include the first wire layer ML1 located within insulation and the second wire layer MLA located on the first wire layer ML1.

The contact portion PL may include the pad portion PL1 located within the insulation layer IL, the first connecting portion PL2 located on the pad portion PL1 and located within the protective layer CL, the second connecting portion PL3 located on the first connecting portion PL2 and protruding above the protective layer CL.

The protective pattern PLA may be located between the contact portion PL and the protective layer CL. In more detail, the protective pattern PLA may include the protective pattern PLA located between the pad portion PL1 and the protective layer CL and between the first connecting portion PL2 and the protective layer CL.

The first wire layer ML1 and the second wire layer MLA may include different metal layers. The pad portion PL1 of the contact portion PL may include the same metal as the first wire layer ML1, and the protective pattern PLA may include the same metal as the second wire layer MLA. For example, the first wire layer ML1 may include copper, and the second wire layer MLA may include nickel. However, the embodiment is not limited thereto.

The pad portion PL1 of the contact portion PL may be directly connected to the first connecting portion PL2 of the contact portion PL, and the second connecting portion PL3 of the contact portion PL may be directly connected to the first connecting portion PL2 of the contact portion PL.

Unlike the printed circuit boards 100, 101, and 102 according to the embodiments described above, in the printed circuit board 103 according to the present embodiment, the protective layer CL1 may have photosensitivity. For example, the protective layer CL1 may include photo-imageable dielectric (PID) that may function as an insulation layer and at the same time enable the photoresist process. However, the embodiment is not limited thereto.

In addition, unlike the printed circuit boards 100, 101, and 102 according to the embodiments described above, in the printed circuit board 103 according to the present embodiment, along the planar direction DRW, the first width W1 of the second connecting portion PL3 of the contact portion PL and the second width W2 of the first connecting portion PL2 of the contact portion PL may be substantially the same. The term “substantially the same” may mean that the first and second widths differ by less than 1%. Along the height direction DRH, the second width W2 of the first connecting portion PL2 of the contact portion PL may be substantially constant. The term “substantially constant” may mean that the widths of the first connecting portion PL2 at different heights differ by less than 1%.

According to the present embodiment, similar to the embodiments described above, as the pad portion PL1 of the contact portion PL and the first connecting portion PL2 of the contact portion PL are directly connected to each other without an intermediate layer such as a seed layer, connection properties between the pad portion PL1 of the contact portion PL and the first connecting portion PL2 and the second connecting portion PL3 of the contact portion PL may be enhanced, and the occurrence of alignment errors may be reduced.

In addition, since the protective pattern PLA is located between the pad portion PL1 and the protective layer CL and between the first connecting portion PL2 and the protective layer CL such that the second connecting portion PL3 of the contact portion PL is protected during the manufacturing process, recesses or the like may not occur on the surface of the second connecting portion PL3 of the contact portion PL protruded on the protective layer CL, such that deterioration of contact properties with respect to the contact portion PL and external electronic devices may be prevented.

Various features of printed circuit boards according to the embodiments described above may be all applicable to a printed circuit board according to the present embodiment.

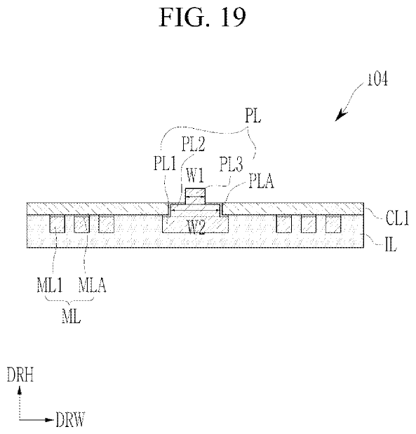

Referring to FIG. 19, a printed circuit board 104 according to another embodiment will be described. FIG. 19 is a cross-sectional view of a printed circuit board according to another embodiment.

Referring to FIG. 19, the printed circuit board 104 according to the present embodiment is similar to printed circuit boards according to the printed circuit boards 100, 101, 102, and 103 described above. The detailed description of the same components is omitted.

Referring to FIG. 19, the printed circuit board 104 according to the present embodiment may include the insulation layer IL, the protective layer CL1 located on the insulation layer IL, the plurality of wire layers ML located within the insulation layer IL, and the contact portion PL partially located within the insulation layer IL and the protective layer CL1 and including the portion protruding from the protective layer CL1.

The plurality of wire layers ML may include the first wire layer ML1 located within insulation and the second wire layer MLA located on the first wire layer ML1.

The contact portion PL may include the pad portion PL1 located within the insulation layer IL, the first connecting portion PL2 located on the pad portion PL1 and located within the protective layer CL, the second connecting portion PL3 located on the first connecting portion PL2 and protruding above the protective layer CL.

The protective pattern PLA may be located between the contact portion PL and the protective layer CL. In more detail, the protective pattern PLA may include the protective pattern PLA located between the pad portion PL1 and the protective layer CL and between the first connecting portion PL2 and the protective layer CL.

The first wire layer ML1 and the second wire layer MLA may include different metal layers. The pad portion PL1 of the contact portion PL may include the same metal as the first wire layer ML1, and the protective pattern PLA may include the same metal as the second wire layer MLA. For example, the first wire layer ML1 may include copper, and the second wire layer MLA may include nickel. However, the embodiment is not limited thereto.

The pad portion PL1 of the contact portion PL may be directly connected to the first connecting portion PL2 of the contact portion PL, and the second connecting portion PL3 of the contact portion PL may be directly connected to the first connecting portion PL2 of the contact portion PL.

Unlike the printed circuit boards 100, 101, and 102 according to the embodiments described above, in the printed circuit board 104 according to the present embodiment, the protective layer CL1 may have photosensitivity. For example, the protective layer CL1 may include photo-imageable dielectric (PID) that may function as an insulation layer and at the same time enable the photoresist process. However, the embodiment is not limited thereto.

In addition, unlike the printed circuit boards 100, 102, and 103 according to the embodiments described above, in the printed circuit board 104 according to the present embodiment, along the planar direction DRW, the second width W2 of the first connecting portion PL2 of the contact portion PL may be wider than the first width W1 of the second connecting portion PL3 of the contact portion PL. Even if an external force is applied to the second connecting portion PL3 of the contact portion PL, the influence of the external force is diffused to the first connecting portion PL2 of the contact portion PL, which has a relatively wider width, and thereby concentration of stress due to external force to the second connecting portion PL3 of the contact portion PL may be prevented, such that damage of the contact portion PL due to external stress may be prevented.

Along the height direction DRH, the first width W1 of the second connecting portion PL3 of the contact portion PL may be substantially constant, and the second width W2 of the first connecting portion PL2 of the contact portion PL may be substantially constant.

According to the present embodiment, similar to the embodiments described above, as the pad portion PL1 of the contact portion PL and the first connecting portion PL2 of the contact portion PL are directly connected to each other without an intermediate layer such as a seed layer, connection properties between the pad portion PL1 of the contact portion PL and the first connecting portion PL2 and the second connecting portion PL3 of the contact portion PL may be enhanced, and the occurrence of alignment errors may be reduced.

In addition, since the protective pattern PLA is located between the pad portion PL1 and the protective layer CL and between the first connecting portion PL2 and the protective layer CL such that the second connecting portion PL3 of the contact portion PL is protected during the manufacturing process, recesses or the like may not occur on the surface of the second connecting portion PL3 of the contact portion PL protruded on the protective layer CL, such that deterioration of contact properties with respect to the contact portion PL and external electronic devices may be prevented.

Various features of printed circuit boards according to the embodiments described above may be all applicable to a printed circuit board according to the present embodiment.

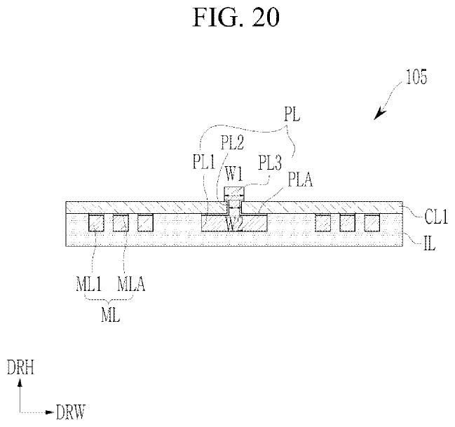

Referring to FIG. 20, a printed circuit board 105 according to another embodiment will be described. FIG. 20 is a cross-sectional view of a printed circuit board according to another embodiment.

Referring to FIG. 20, the printed circuit board 105 according to the present embodiment is similar to the printed circuit boards 100, 101, 102, 103, and 104 according to the embodiments described above. The detailed description of the same components is omitted.

Referring to FIG. 20, the printed circuit board 105 according to the present embodiment may include the insulation layer IL, the protective layer CL1 located on the insulation layer IL, the plurality of wire layers ML located within the insulation layer IL, and the contact portion PL partially located within the insulation layer IL and the protective layer CL1 and including the portion protruding from the protective layer CL1.

The plurality of wire layers ML may include the first wire layer ML1 located within insulation and the second wire layer MLA located on the first wire layer ML1.

The contact portion PL may include the pad portion PL1 located within the insulation layer IL, the first connecting portion PL2 located on the pad portion PL1 and located within the protective layer CL, the second connecting portion PL3 located on the first connecting portion PL2 and protruding above the protective layer CL.

The protective pattern PLA may be located between the contact portion PL and the protective layer CL. In more detail, the protective pattern PLA may include the protective pattern PLA located between the pad portion PL1 and the protective layer CL and between the first connecting portion PL2 and the protective layer CL.

The first wire layer ML1 and the second wire layer MLA may include different metal layers. The pad portion PL1 of the contact portion PL may include the same metal as the first wire layer ML1, and the protective pattern PLA may include the same metal as the second wire layer MLA. For example, the first wire layer ML1 may include copper, and the second wire layer MLA may include nickel. However, the embodiment is not limited thereto.

The pad portion PL1 of the contact portion PL may be directly connected to the first connecting portion PL2 of the contact portion PL, and the second connecting portion PL3 of the contact portion PL may be directly connected to the first connecting portion PL2 of the contact portion PL.

Unlike the printed circuit boards 100, 101, and 102 according to the embodiments described above, in the printed circuit board 105 according to the present embodiment, the protective layer CL1 may have photosensitivity. For example, the protective layer CL1 may include photo-imageable dielectric (PID) that may function as an insulation layer and at the same time enable the photoresist process. However, the embodiment is not limited thereto.

In addition, unlike the printed circuit boards 100, 101, 103, and 104 according to the embodiments described above, in the printed circuit board 104 according to the present embodiment, along the planar direction DRW, the first width W1 of the second connecting portion PL3 of the contact portion PL may be wider than the second width W2 of the first connecting portion PL2 of the contact portion PL. Even if the width of the first connecting portion PL2 of the contact portion PL located within the protective layer CL is narrow, the second connecting portion PL3 of the contact portion PL may be formed wide, and accordingly, deterioration of contact properties with respect to external electronic devices may be prevented.

Along the height direction DRH, the first width W1 of the second connecting portion PL3 of the contact portion PL may be substantially constant, and the second width W2 of the first connecting portion PL2 of the contact portion PL may be substantially constant.

According to the present embodiment, similar to the embodiments described above, as the pad portion PL1 of the contact portion PL and the first connecting portion PL2 of the contact portion PL are directly connected to each other without an intermediate layer such as a seed layer, connection properties between the pad portion PL1 of the contact portion PL and the first connecting portion PL2 and the second connecting portion PL3 of the contact portion PL may be enhanced, and the occurrence of alignment errors may be reduced.

In addition, since the protective pattern PLA is located between the pad portion PL1 and the protective layer CL and between the first connecting portion PL2 and the protective layer CL such that the second connecting portion PL3 of the contact portion PL is protected during the manufacturing process, recesses or the like may not occur on the surface of the second connecting portion PL3 of the contact portion PL protruded on the protective layer CL, such that deterioration of contact properties with respect to the contact portion PL and external electronic devices may be prevented.

Various features of printed circuit boards according to the embodiments described above may be all applicable to a printed circuit board according to the present embodiment.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A printed circuit board, comprising:
an insulation layer;
a wire layer located within the insulation layer;
a protective layer located on the insulation layer;
a contact portion comprising:
a first connecting portion located within the insulation layer and the protective layer, and
a second connecting portion protruding above the protective layer; and
a protective pattern located between the protective layer and the first connecting portion of the contact portion.

2. The printed circuit board of claim 1, wherein the first connecting portion of the contact portion comprises a pad portion located within the insulation layer, and a first connecting portion located within the protective layer.

3. The printed circuit board of claim 2, wherein the pad portion and the first connecting portion are directly connected.

4. The printed circuit board of claim 3, wherein the first connecting portion and the second connecting portion are integrally formed.

5. The printed circuit board of claim 4, wherein the contact portion and the protective pattern comprise different metals.

6. The printed circuit board of claim 5, wherein a thickness of the protective pattern is thinner than a thickness of the pad portion of the contact portion and a thickness of the first connecting portion of the contact portion.

7. The printed circuit board of claim 1, wherein:
the wire layer comprises a first wire layer, and a second wire layer located on the wire layer;
the first wire layer comprises the same metal as the contact portion; and
the second wire layer comprises the same metal as the protective pattern.

8. The printed circuit board of claim 7, wherein a thickness of the second wire layer is thinner than a thickness of the first wire layer.

9. The printed circuit board of claim 3, wherein, along a height direction, a first width of the second connecting portion is substantially constant.

10. The printed circuit board of claim 3, wherein, along a planar direction that is substantially parallel to a surface of the insulation layer, a first width of the second connecting portion and a second width of the first connecting portion are different from each other.

11. The printed circuit board of claim 10, wherein, along a height direction that is substantially perpendicular to the planar direction, the second width of the first connecting portion is substantially constant.

12. The printed circuit board of claim 10, wherein, along a height direction that is substantially perpendicular to the planar direction, the second width of the first connecting portion narrows toward the second connecting portion.

13. The printed circuit board of claim 3, wherein, along a planar direction that is substantially parallel to a surface of the insulation layer, a first width of the second connecting portion and a second width of the first connecting portion are substantially the same.

14. A manufacturing method of a printed circuit board, comprising:
forming a dummy insulation layer having a first hole;
stacking a protective layer on the dummy insulation layer, and forming a second hole overlapping the first hole in the protective layer;
stacking a protective metal layer on the protective layer and within the first hole and the second hole;
integrally forming a first connecting portion and a second connecting portion within the first hole and the second hole covered with the protective metal layer;
forming a pad portion and a wire layer on the protective metal layer;
stacking the insulation layer on the pad portion and the wire layer;
exposing the protective metal layer located on the second connecting portion by removing the dummy insulation layer; and
forming a protective pattern located between the protective layer and the pad portion and between the first connecting portion and the protective layer by removing the protective metal layer on the second connecting portion.

15. The manufacturing method of a printed circuit board of claim 14, wherein the pad portion and the first connecting portion are directly connected.

16. The manufacturing method of a printed circuit board of claim 15, wherein:
the contact portion and the protective pattern comprise different metals; and
a thickness of the protective pattern is thinner than a thickness of the pad portion and a thickness of the first connecting portion.

17. The manufacturing method of claim 14, wherein:
the wire layer comprises a first wire layer, and a second wire layer located on the wire layer;
the first wire layer comprises the same metal as the contact portion;
the second wire layer comprises the same metal as the protective pattern; and
a thickness of the second wire layer is thinner than a thickness of the first wire layer.

18. The printed circuit board of claim 15, wherein, along a height direction that is perpendicular to a planar direction, a first width of the second connecting portion is substantially constant.

19. The printed circuit board of claim 15, wherein, along a planar direction that is substantially parallel to a surface of the insulation layer, a first width of the second connecting portion and a second width of the first connecting portion are different from each other.

20. The printed circuit board of claim 19, wherein, along a height direction that is substantially perpendicular to the planar direction, the second width of the first connecting portion is substantially constant.

21. The printed circuit board of claim 15, wherein along a planar direction that is substantially parallel to a surface of the insulation layer, a first width of the second connecting portion and a second width of the first connecting portion are substantially the same.
